(19) United States
(12) Patent Application Publication
(10) Pub. No.: US 2012/0033473 A1
(43) Pub. Date: Feb. 9, 2012

(54) SYSTEMS AND METHODS FOR ELECTRICAL POWER GRID MONITORING USING LOOSELY SYNCHRONIZED PHASORS

(76) Inventor: Mesa P. Scharf, Redmond, OR (US)

(21) Appl. No.: 13/181,216

(22) Filed: Jul. 12, 2011

Related U.S. Application Data
(60) Provisional application No. 61/363,643, filed on Jul. 12, 2010.

(51) Int. Cl. H02M 7/537; G01R 27/28

(52) U.S. Cl. 363/131; 324/650

(57) ABSTRACT

The present disclosure describes systems and methods for monitoring an electrical power grid using loosely synchronized phasors. The grid can include a phasor measurement unit (PMU) that keeps a highly-accurate time, such as a time provided by GPS signals. A solar power inverter can include a clock that is synchronized to a less-accurate time, such as a time provided by a public time server or a radio time signal. The inverter can also include a PMU that generates phasors timestamped according to the less-accurate time. The inverter can receive phasors from the grid PMU. Although the grid and inverter phasors can be loosely synchronized in time, the inverter can analyze the grid and inverter phasors to determine a state of the grid. For example, the inverter can calculate a Pearson's correlation coefficient based on the grid and inverter phasors, and use the result to determine a state of the grid.

### CROSS-REFERENCE TO RELATED APPLICATIONS

This application claims the benefit of U.S. Provisional Patent Application No. 61/363,643 filed Jul. 12, 2010 (entitled SYSTEMS AND METHODS FOR ELECTRICAL POWER GRID MONITORING USING LOOSELY SYNCHRONIZED PHASORS) which is related to the following applications: U.S. Provisional Patent Application No. 61/355,119 filed Jun. 15, 2010 (entitled GRID INTEGRATION OF PHOTOVOLTAIC INVERTERS WITH A NOVEL ISLAND DETECTION TECHNIQUE); U.S. Provisional Patent Application No. 61/363,634 filed Jul. 12, 2010 (entitled SYSTEMS AND METHODS FOR ISLANDING DETECTION, Attorney Docket No. 65564-8026.US01); and U.S. Provisional Patent Application No. 61/363,632 filed Jul. 12, 2010 (entitled SYSTEMS AND METHODS FOR DYNAMIC POWER COMPENSATION, SUCH AS DYNAMIC POWER COMPENSATION USING SYNCHROPHASORS, Attorney Docket No. 65564-8025.US01), each of which is also incorporated herein by reference in its entirety.

### TECHNICAL FIELD

This application is generally directed toward power generation systems.

### BACKGROUND

An electrical power grid may include phasor measurement units (PMUs) at various locations of the electrical power grid. The PMUs measure characteristics of the electrical power (e.g., voltage and current) generated by or transmitted over the electrical power grid and produce phasors representative of the measurements. Such PMUs typically include a global positioning system (GPS) clock that uses a GPS signal that is accurate to approximately 1 microsecond (1 μs). The PMUs timestamp the phasors with the GPS-synchronized clock time. Phasors that are generated at the same, highly-accurate, time are known as synchrophasors. Synchrophasors can be analyzed, such as in real time, so as to monitor aspects of the electrical power grid.

One disadvantage to such a system is that a GPS clock and associated equipment (e.g., antenna) may add additional costs to the installation and use of a PMU. Such additional costs may preclude the installation of PMUs in certain locations where it would nonetheless be desirable to have information regarding the electrical power transmitted by the electrical power grid at such locations.

### BRIEF DESCRIPTION OF THE DRAWINGS

FIG. 1 is a diagram illustrating a system for electrical power grid monitoring configured in accordance with an embodiment of the technology.

FIG. 2 is a block diagram illustrating components of a solar power inverter configured in accordance with an embodiment of the technology.

FIG. 3 is a flow diagram of a process for monitoring an electrical power grid in accordance with an embodiment of the technology.

FIGS. 4A and 4B are flow diagrams of processes for analyzing grid and inverter phasors in accordance with an embodiment of the technology.

### DETAILED DESCRIPTION

### 1. Overview

The inventor has recognized that the need exists for systems and methods that overcome the above disadvantage, as well as provide additional benefits. The present disclosure describes systems and methods for monitoring an electrical power grid using loosely synchronized phasors. The electrical power grid can include a PMU that is time synchronized to a highly-accurate time, such as a time provided by GPS signals. A solar power inverter can include a clock that is synchronized to a time that is less accurate than the time provided by the GPS signals. For example, the solar power inverter can synchronize its time to an Internet or Intranet time server and/or to a time signal broadcast over the radio spectrum. The solar power inverter can also include a PMU that generates phasors that are timestamped using the less-accurate inverter clock time. The solar power inverter can receive phasors from the electrical power grid PMU and analyze the grid and inverter phasors. For example, the solar power inverter can calculate a Pearson's correlation coefficient based on the grid and inverter phasors. As another example, the solar power inverter can calculate slip and acceleration quantities using the grid and inverter phasors.

The solar power inverter can use the analysis of the grid and inverter phasors (e.g., the Pearson's correlation coefficients, or the slip and acceleration quantities) to determine a state of the electrical power grid at the point of common coupling of the solar power inverter to the electrical power grid. Such information can enable the solar power inverter to take certain actions based upon the analysis. For example, if the analysis indicates that the solar power inverter is islanded from the electrical power grid, the solar power inverter can shut down (stop producing power). Alternatively, the solar power inverter can shift to an intentional island mode, in which a connection to the electrical power grid is opened and the solar power inverter produces power to support a local load. As another example, if the analysis indicates that the electrical power grid is stable but that certain grid support functionality may be useful, the solar power inverter can remain connected to the electrical power grid and provide such support functionality.

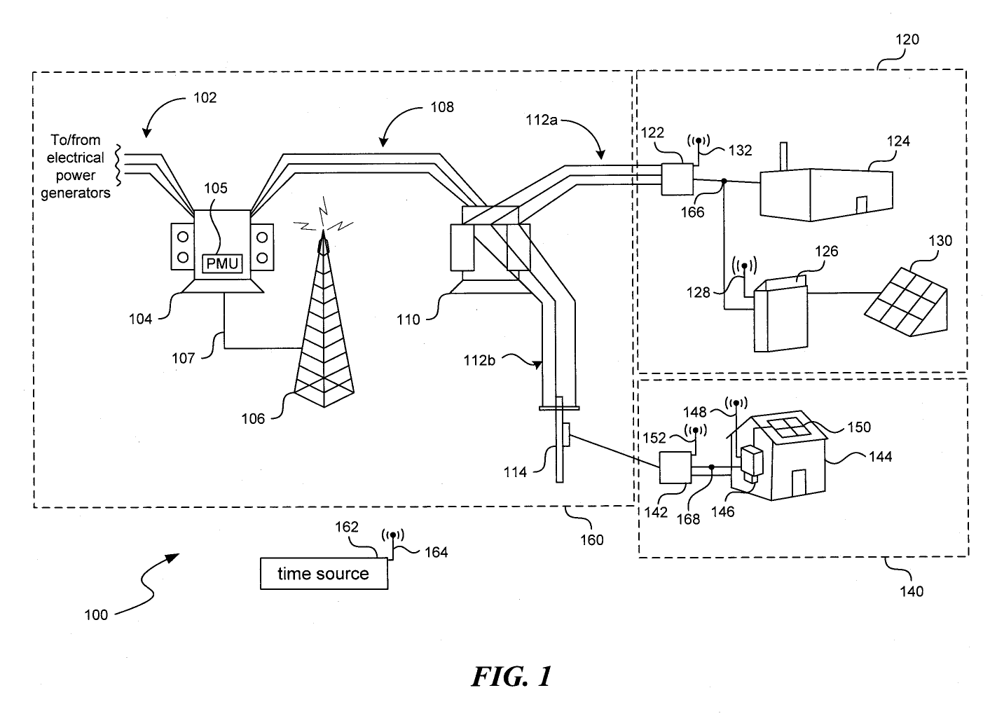

Certain details are set forth in the following description and in FIGS. 1-4B to provide a thorough understanding of various embodiments of the technology. Other details describing well-known aspects of power generation systems, solar power inverters, and phasors, however, are not set forth in the following disclosure so as to avoid unnecessarily obscuring the description of the various embodiments.

Many of the details, dimensions, angles and other features shown in the Figures are merely illustrative of particular embodiments. Accordingly, other embodiments can have other details, dimensions, angles and features. In addition, further embodiments can be practiced without several of the details described below.

In the Figures, identical reference numbers identify identical, or at least generally similar, elements. To facilitate the discussion of any particular element, the most significant digit or digits of any reference number refer to the Figure in which that element is first introduced. For example, element 100 is first introduced and discussed with reference to FIG. 1.

### 2. Systems and Methods for Electrical Power Grid Monitoring

FIG. 1 is a diagram illustrating a system 100 for monitoring an electrical power grid configured in accordance with an embodiment of the technology. The system 100 includes a utility grid portion 160 and multiple customer premises portions 120 and 140. The utility grid portion 160 includes electrical power transmission lines 102 electrically connected to a transmission substation 104. The electrical power transmission lines carry three phase alternating current (AC) generated by one or more electrical power generators. The transmission substation 104 steps down the voltage of the AC (e.g., from 345 kilo Volts (kV) to 69 kV, or from any particular voltage to a lower voltage) before transmission of the AC over electrical power transmission lines 108 to a distribution substation 110. The distribution substation 110 further steps down the voltage of the AC (e.g., to 13.8 kV, or to any other voltage) prior to transmission over electrical transmission lines 112a to a first customer premises portion 120 and over electrical transmission lines 112b to a distribution device 114 and then to a second customer premises portion 140.

The transmission substation 104 includes a phasor measurement unit (PMU) 105. The PMU 105 measures characteristics of the AC at the transmission substation 104 and generates phasors based on the measured characteristics of the AC. The PMU 105 includes a Global Positioning System (GPS) antenna and clock that allow the PMU 105 to timestamp the generated phasors with a highly accurate time, e.g., on the order of +/−1 microsecond (1 μs). The phasors generated by the PMU 105 are thus associated with times that are accurate to a first degree of accuracy. The transmission substation 104 is networked via a communication channel 107 to a transceiver 106. The transceiver 106 receives the phasors from the PMU 105 via the communication channel 107 and transmits the phasors.

The first customer premises portion 120 includes an industrial load 124, one direct current (DC) from solar irradiance and provide the DC to the inverter 126. The inverter 126 converts the DC into AC usable by the industrial load 124 or the electrical power grid. The inverter 126 is coupled to a transceiver 128. As described in more detail herein, the transceiver 128 receives phasors transmitted from the transceiver 106 as well as time signals. The first customer premises portion 120 can also include a switch 122 near or at the point of common coupling (PCC) 166 of the inverter 126 to the electrical power grid. The switch 122 includes a transceiver 132. The switch 122 can receive, via the transceiver 132, information transmitted by the transceiver 106 and/or the transceiver 128.

The second customer premises portion 140 includes a residential load 144, an array 150 of photovoltaic cells, and an inverter 146. The array 150 produces DC and provides the DC to the inverter 146, which converts the DC into AC usable by the residential load 144 or the electrical power grid. The inverter 146 is communicably coupled to a transceiver 148. As described in more detail herein, the transceiver 148 receives phasors transmitted from the transceiver 106 as well as time signals. The second customer premises portion 140 can also include a switch 142 at the PCC 168 of the inverter 146 to the electrical power grid. The switch 142 includes a transceiver 152. The switch 142 can receive, via the transceiver 152, information transmitted by the transceiver 106 and/or the transceiver 148.

The system 100 also includes a time source 162 that includes a transceiver 164. The time source 162 provides a time signal indicating time. For example, the time source 162 can include a Network Time Protocol (NTP) server. Such NTP servers may provide time accurate to within 10 milliseconds (1 ms) over the public Internet, and may achieve accuracies of 200 microseconds (200 μs) over a private Intranet. As another example, the time source 162 can include a National Institute of Standards and Technology (NIST) radio station that broadcasts a time signal. A clock that uses the NIST signal typically can maintain time accurate to approximately +/−1 second (1 s). As described in more detail herein, the inverters 126/146 receive the time signal from the time source 162 and use the time signal to synchronize their respective internal clocks. The time signals may indicate their degree of accuracy, or the inverter 126/146 may determine a degree of accuracy based upon the time signal and/or the time source 162. For example, the inverter 126/146 may assume that time from an NTP server sourced over the public Internet is accurate to within 10 ms, or that time from an NIST signal is accurate to within 1 second. The inverter 126/146 may use other information to determine an accuracy of the time provided by the time source 162.

As illustrated in FIG. 1 the transceivers 106/128/132/148/152/164 are shown as wireless transmission and reception devices that transmit and receive information wirelessly. However, the transceivers 106/128/132/148/152/164 can be any suitable device for transmitting and receiving information over any suitable communication channel (e.g., a wireless network such as WiFi, WiMax, a cellular/GSM network, ZigBee, Advanced Metering Infrastructure (AMI), etc., a wired network such as a fiber network, an Ethernet network, etc., or any combination of wired and wireless networks). Accordingly, the techniques described herein are usable in conjunction with any suitable communication channel.

The system 100 can also include other components coupled to the electrical power grid that are not specifically illustrated. Such components can include other loads (e.g., inductive loads such as a transformer or motor), other electrical components (e.g., capacitor banks), other types of electrical power generation systems (e.g., wind power generation systems and/or other renewable power generation systems), and other components. Activity of loads or other components on the electrical power grid can cause voltage sags or swells and can be accompanied by reactive power flow, thereby resulting in less than ideal power to the load 124/144, such as voltage that falls outside of a predetermined range that the load 124/144 utilizes, (e.g., ideally utilizes). Such out-of-range voltage can damage the load 124/144 and/or cause the load 124/144 to work harder. The activity of loads or other components on the electrical power grid can also cause overload conditions or other problems that are detectable at the PCCs 166/168 of the inverters 126/146 to the electrical power grid. As described in more detail herein, the inverters 126/146 can utilize loosely synchronized phasors to monitor the condition or state of the electrical power grid at the PCCs 166/168. When the inverters 126/146 detect certain conditions at the PCCs 166/168, the inverters 126/146 can perform appropriate actions in response to such conditions.

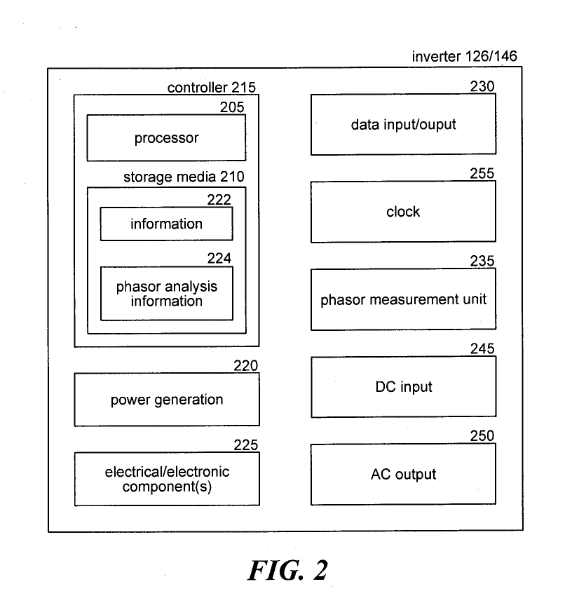

FIG. 2 is a block diagram illustrating components of the solar power inverter 126/146. The solar power inverter 126/146 can also include components that are not illustrated in FIG. 2. The solar power inverter 126/146 includes a DC input component 245 that receives DC produced by the arrays 130/150. The solar power inverter 126/146 also includes power generation component 220, such as insulating gate bipolar transistors (IGBTs), which transforms DC into AC for output by an AC output component 250. The solar power inverter 126/146 further includes various other electrical and/or electronic components 225, such as circuit boards, capacitors, transformers, inductors, electrical connectors, and/or other components that perform and/or enable performance of various functions associated with the conversion of DC into AC and/or other functions described herein. The solar power inverter 126/146 also includes one or more data input/output components 230, which can include the transceiver 128/148 and/or other components that provide data input/output functionality and/or connection to a wired or wireless network (e.g., an AMI device, a modem, an Ethernet network card, Gigabit Ethernet network card, etc.).

The solar power inverter 126/146 further includes a PMU 235 that measures characteristics of the AC produced by the power generation component 220 and generates phasors based on the measured characteristics. The PMU 235 can measure the characteristics of the AC at a location electrically proximate to the power generation component 220. The solar power inverter 126/146 further includes a clock 255. The solar power inverter 126/146 receives time signals via the transceiver 128/148 from the time source 162. The clock 255 has a time that is set according to the time signals. Because the time signals from the time source 162 are less accurate than the GPS (or other high-accuracy) time signals used by PMU 105, the time of the clock 255 is less accurate than the GPS clock time of the PMU 105. The PMU 235 uses the clock time to associate times with the inverter phasors (timestamp the inverter phasors). Accordingly, the inverter phasors are associated with times that are accurate to a second degree of accuracy that is less than the first degree of accuracy of the times of the grid phasors. In some cases, the inverter phasors times may be one or more orders of magnitude less accurate than the grid phasors times.

The clock 255 can synchronize its time to the time source 162 time signals periodically (e.g., every hour, every 2 hours, every 24 hours, etc.). In some embodiments, the clock 255 synchronizes its time to a time in a grid phasor. In such cases, the accuracy of the clock 255 time would be dependent upon the latency of the connection between the PMU 105 and the inverter 126/146.

In some embodiments, the solar power inverter 126/146 receives AC from the electrical power grid (for example, via the AC output component) that is used to power the solar power inverter 126/146. In such embodiments, the PMU 235 can measure the characteristics of the received AC even if the inverter 126/146 is not generating AC. In some embodiments, the PMU 235 is external to the solar power inverter 126/146. For example, the PMU 235 may be sited at the PCC 166/168 and can measure the characteristics of the AC at such location. A site may have multiple solar power inverters 126/146 with a single PCC 166/168 and a PMU 235 at the PCC 166/168. The PMU 235 can measure the characteristics of the AC at the PCC 166/168 and transmit the synchrophasors to the multiple solar power inverters 126/146. In such a configuration the solar power inverters 126/146 can act independently or collectively to monitor the electrical power grid using the synchrophasors from the PMU 105 (which may be referred to herein as reference synchrophasors) and synchrophasors from the PMU 235 (which may be referred to herein as local synchrophasors).

The solar power inverter 126/146 further includes a controller 215, which includes a processor 205 and one or more storage media 210. For example, the controller 215 can include a control board having a digital signal processor (DSP) and associated storage media. As another example, the controller 215 can include a computing device (for example, a general purpose computing device) having a central processing unit (CPU) and associated storage media. The storage media 210 can be any available media that can be accessed by the processor 205 and can include both volatile and nonvolatile media, and removable and non-removable media. By way of example, and not limitation, the storage media 210 can include volatile and nonvolatile, removable and non-removable media implemented via a variety of suitable methods or technologies for storage of information. Storage media include, but are not limited to, RAM, ROM, EEPROM, flash memory or other memory technology, or any other medium (for example, magnetic disks) which can be used to store the desired information and which can accessed by the processor 205.

The storage media 210 stores information 222. The information 222 includes instructions, such as program modules, that are capable of being executed by the processor 205. Generally, program modules include routines, programs, objects, algorithms, components, data structures, and so forth, which perform particular tasks or implement particular abstract data types. The information 222 also includes data, such as values stored in memory registers, which can be accessed or otherwise used by the processor 205. The processor 205 can use the information 222 to perform various functions or cause various functions to be performed. The storage medium also stores phasor analysis information 224. As described in more detail herein, the processor 205 can use the phasor analysis information 224 to, among other things, analyze grid and inverter phasors, determine a state of the electrical power grid based on the analysis, and/or to perform actions based on the state of the electrical power grid.

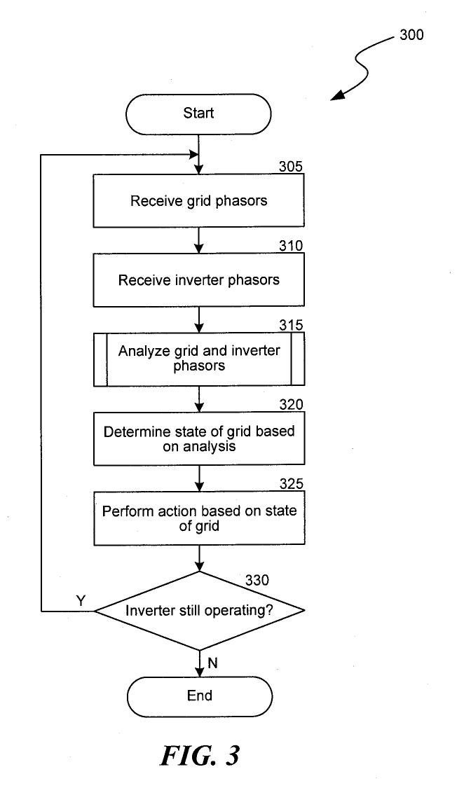

FIG. 3 is a flow diagram of a process 300 for monitoring an electrical power grid in accordance with an embodiment of the technology. The process 300 is described as performed by the controller 215 of the solar power inverter 126/146. However, any suitable component of the solar power inverter 126/146 can perform the process 300. Additionally or alternatively, any suitable apparatus or system with appropriate hardware (e.g., central processing unit (CPU), etc.), firmware (e.g., logic embedded in microcontrollers, etc.), and/or software (e.g., stored in volatile or non-volatile memory) can perform the process 300. The controller 215 can perform the process 300 on a periodic or an ad-hoc basis. For example, the controller 215 can perform the process at the same rate at which the controller 215 receives phasors from the grid (described below).

The process 300 begins at step 305, where the controller 215 receives phasors received by the data input/output component 230 (e.g., phasors transmitted by the transceiver 106). In FIG. 1, the transmission substation 104 includes the PMU 105 that generates phasors that the transceiver 106 transmits. Additionally or alternatively, other components of the utility grid portion 160 (e.g., the distribution substation 110, the distribution device 114, and/or electrical power generators) can include a PMU that generates phasors that are transmitted (e.g., wirelessly or by another suitable communication channel) to the solar power inverter 126/146. Phasors derived from or generated based upon measurements taken of AC transmitted by the electrical power grid are referred to herein as grid phasors. The PMU 105 can measure characteristics of the AC and generate phasors at any suitable sampling rate, such as a sampling rate from approximately 5 Hz or more to approximately 120 Hz or more (e.g., approximately 5 samples per second to approximately 120 samples per second or more). The PMU 105 can transmit the samples at the same rate as the sampling rate. The controller 215 can receive phasors at the same rate as the sampling rate and perform the process 300 at the same rate.

At step 310 the controller 215 receives the phasors that are generated by the PMU 235 based on measurements of characteristics of the AC generated by the power generation component 220. The PMU 235 can generate phasors at the same sampling rate as the PMU 105. Phasors derived from or generated based upon measurements taken of AC generated by the power generation component 220 (or at an electrically proximate location) are referred to herein as inverter phasors.

As previously noted, the grid phasors generated by the PMU 105 of the transmission substation 104 can be timestamped with a highly-accurate time (e.g., to within 1 μs). The inverter phasors, however, are timestamped with a less accurate time (e.g., to within approximately 200 μs, to within 10 ms, or to within a second). Accordingly, the timestamping of the inverter phasors may be less accurate than the timestamping of the grid phasors. In some cases, the times of the inverter phasors may be one or more orders of magnitude less accurate than the times of the grid phasors. Such reduced accuracy may mean that the inverter phasors correspond to different AC cycles than the grid phasors. For example, in a 60 kHz system, if the inverter clock time is accurate to within 50 ms, then there could be up to three cycles of slip between the grid phasors and the inverter phasors (50 ms corresponds to 3 AC cycles in a 60 kHz system). However, despite these differences, it is still likely that analysis of the grid and inverter phasors can provide useful results, as described in more detail herein.

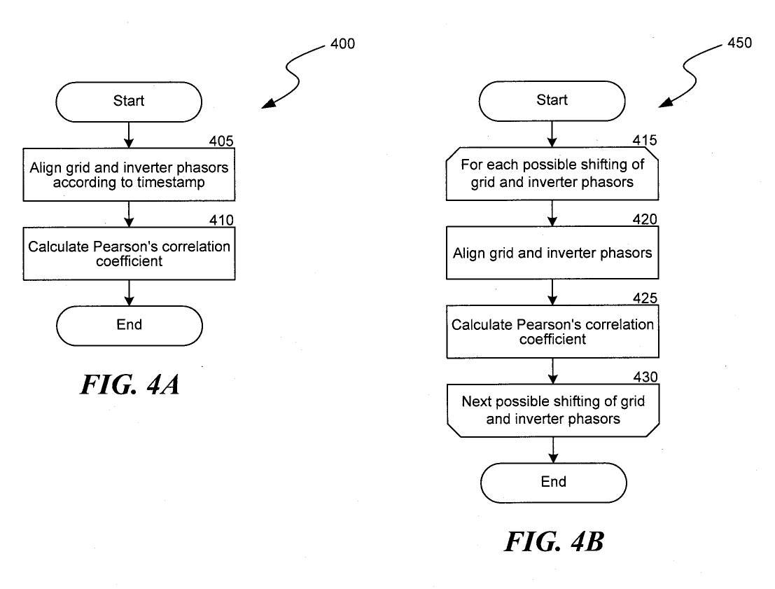

At step 315 the controller 215 analyzes the grid and inverter phasors. FIG. 4A is a flow diagram of a process 400 that the controller 215 can perform to analyze the grid and inverter phasors. The process 400 begins at step 405, where the controller 215 aligns a set of grid and inverter phasors according to their timestamps (e.g., the controller aligns the grid and inverter phasors having timestamps at t₀, t₁, t₂, and so on). At step 410 the controller 215 calculates the Pearson's correlation coefficient for the grid and inverter phasors. More details as to how the Pearson's correlation coefficient can be calculated using phasors can be found in the previously referred to U.S. Pat. App. No. 61/363,634 (entitled SYSTEMS AND METHODS FOR ISLANDING DETECTION, Attorney Docket No. 65564-8026.US01). The Pearson's correlation coefficient indicates a degree of correlation between the grid and the inverter phasors, which can be used to infer the state of the electrical power grid. For example, in an problem condition such as a line down or an overload, the grid and inverter phasors would likely be uncorrelated and such lack of correlation would be quantified by the Pearson's correlation coefficient.

Even though there may be several cycles of AC slip between the grid and inverter phasors due to the different time accuracies, the grid and inverter phasors are likely to be correlated as long as the electrical power grid is not experiencing a problem condition. Put another way, if the inverter 126/146 is truly islanded from the electrical power grid, the probability that the grid and the inverter phasors are uncorrelated is very high, regardless of whether there are multiple cycles of slip between the grid and the inverter phasors. The lack of such correlation, as indicated by the Pearson's correlation coefficient, would indicate a high probability that the state of the electrical power grid at the PCC 166/168 is abnormal, and thus that the inverter 126/146 should perform an appropriate action. After step 410, the process 400 concludes.

FIG. 4B is a flow diagram of a process 450 that the controller 215 can use to analyze the grid and inverter phasors in addition or as an alternative to the process 400 of FIG. 4A. In general, the process 450 involves shifting the inverter phasors 215 over a time window or tolerance interval and calculating the Pearson's correlation coefficient for each possible shift in the time window or tolerance interval. The width of the time window or tolerance interval can be based upon the accuracy of the time of the inverter phasors. Decreasing accuracy of the time of the inverter phasors would tend to increase the width of the time window or tolerance interval. For example, where the accuracy of the time of the inverter phasors is to within 50 ms, the time window or tolerance interval over which the inverter phasors can be shifted is likely to be narrower than the time window or tolerance interval where the accuracy of the time of the inverter phasors is to within 1 second.

The process 450 begins at step 415, where the controller 215 determines possible shifts in the time window of the grid and inverter phasors. At step 420 the controller aligns the grid and inverter phasors according to a first possible shifting. The controller 215 can hold the grid phasors constant and shift the inverter phasors. Alternatively, the controller 215 can shift the grid phasors relative to the inverter phasors. At step 425 the controller 215 calculates the Pearson's correlation coefficient for the grid and inverter phasors. At step 430 the controller determines if there is another possible alignment of the grid and inverter phasors. If so, the process returns to step 415. If not the process 450 concludes.

The process 450 can result in multiple Pearson's correlation coefficients depending upon the number of shifts of the inverter phasors over the time window. If every Pearson's correlation coefficient that results from the process 450 indicates no correlation between the grid and inverter phasors over multiple consecutive iterations of the process 450, then there is a high likelihood that there is a problem condition at the PCC 166/168 (e.g., such complete lack of correlation may indicate that the inverter 126/146 is islanded.) However, if there is at least one Pearson's correlation coefficient that indicates that the grid and inverter phasors are still correlated, then there is a low likelihood that there is a problem condition at the PCC 166/168 (e.g., at least one correlation may indicate that the inverter 126/146 is still connected to the electrical power grid and that the electrical power grid appears stable).

One advantage of the process 450 is that it can account for time signals from the time source 162 that are less accurate than other sources. For example, a time source 162 that transmits time that is only accurate to within 500 ms can result in a larger time window over which the controller 215 is to shift inverter phasors, and thus result in a larger number of calculations for the controller 215 to perform. However, the controller 215 can be selected so as have enough processing power to perform the necessary calculations within the necessary period of time.

After the processes 400 or 450 of FIG. 4A or 4B conclude, flow returns to step 320 of FIG. 3, where the controller 215 determines a state of the electrical power grid based on the analysis of the grid and inverter phasors. The controller 215 can use the Pearson's correlation coefficients as a basis for determining a state of the electrical power grid. More details as to how the controller 215 can use the Pearson's correlation coefficients in this manner can be found in the previously referred to U.S. Pat. App. No. 61/363,634 (entitled SYSTEMS AND METHODS FOR ISLANDING DETECTION, Attorney Docket No. 65564-8026.US01). For example, certain states at the PCC 166/168 that the controller 215 can detect are: 1) the inverter 126/146 at the PCC 166/168 is islanded; 2) the electrical power grid appears stable, but certain support functions may be required such as low voltage ride through (LVRT) or volt-ampere reactive (VAR) corrections. Those of skill in the art will understand the controller 215 may be able to detect states other than those listed herein.

At step 325 the controller 215 performs an action and/or causes an action to be performed based on the state of the electrical power grid. For example, the controller 215 can cause the inverter 126/146 to shut down or switch to intentional island mode. As another example, the controller 215 can cause the inverter 126/146 to provide grid support functionality such as LVRT or VAR corrections. More details as to how the inverter 126/146 can provide grid support functionality can be found in the previously-referenced U.S. Pat. App. No. 61/363,632 (entitled SYSTEMS AND METHODS FOR DYNAMIC POWER COMPENSATION, SUCH AS DYNAMIC POWER COMPENSATION USING SYNCHROPHASORS, Attorney Docket No. 65564-8025.US01). Those of skill in the art will understand that the controller 215 may be able to perform actions and/or cause to be performed actions other than those listed herein.

At step 330, the controller 215 determines whether the inverter 126/146 is still operating. If so, the process 300 returns to step 305. If not, the process 300 concludes. Those skilled in the art will appreciate that the steps shown in any of FIGS. 3, 4A and 4B may be altered in a variety of ways. For example, the order of the steps may be rearranged; substeps may be performed in parallel; shown steps may be omitted, or other steps may be included; etc.

Another technique for detecting an islanding condition using synchrophasors is referred to as “slip and acceleration.” Slip and acceleration uses a measure of the rate of change of the grid and inverter frequencies (slip) and a measure of the acceleration of the rate of change of the frequencies (acceleration). The controller 215 can use an analysis based on slip and acceleration in addition to or as an alternative to calculating the Pearson's correlation coefficient. For example, in steps 410 and 425, instead of or in addition to calculating the Pearson's correlation coefficient, the controller 215 could calculate slip and acceleration of the grid and inverter phasors. The controller 215 would then determine a state of the grid based upon the calculated slip and acceleration values. Additionally or alternatively, the controller 215 could use other phasor-based techniques.

One advantage of the techniques described herein is that because the inverter 126/146 uses a time signal from an external time source to synchronize the clock 255 time, there can be no need to add the equipment required to obtain a high-accuracy time signal (e.g., a GPS clock and antenna). Since such equipment may be both high cost and difficult to place at certain inverter 126/146 sites, the ability to avoid using such equipment can be a significant advantage to solar power inverters configured as described herein. Another advantage is that a lack of correlation between grid phasors and inverter phasors can likely still be detected despite the inverter phasors having less accurate timestamps. This is because such lack of correlation is highly likely to show up even though the grid and inverter phasors may not be exactly aligned.

### 3. Conclusion

From the foregoing, it will be appreciated that specific embodiments of the invention have been described herein for purposes of illustration, but that various modifications may be made without deviating from the spirit and scope of the invention. For example, although the processes 400/450 are described as calculating the Pearson's correlation coefficient, correlation between the grid phasors and the inverter phasors can be calculated using other techniques. As another example, the elements of one embodiment can be combined with other embodiments in addition to or in lieu of the elements of other embodiments. Accordingly, the invention is not limited except as by the appended claims.

I claim:

1. A solar power inverter comprising:
a direct current (DC) input component configured to receive DC produced by one or more photovoltaic cells;
a power generation component configured to generate alternating current (AC) from the DC produced by the one or more photovoltaic cells;
an AC output component configured to output generated AC, wherein the AC output component is electrically coupleable to an electrical power grid;
one or more data input/output components configured to—
receive signals indicating electrical power grid phasors, wherein the electrical power grid phasors describe characteristics of AC transmitted by the electrical power grid, and wherein the electrical power grid phasors are associated with times having a first degree of accuracy; and
receive time signals indicating time, wherein the time is accurate according to a second degree of accuracy, and wherein the second degree of accuracy is less than the first degree of accuracy;
a clock configured to maintain time and to synchronize the time according to the time indicated by the time signals;
a phasor measurement unit configured to generate inverter phasors and to associate the inverter phasors with the time maintained by the clock, wherein the inverter phasors describe characteristics of AC electrically proximate to the AC output component; and
a controller configured to analyze the electrical power grid phasors and the inverter phasors.

2. The solar power inverter of claim 1 wherein the controller is further configured to:
align the electrical power grid phasors and the inverter phasors according to respective associated times; and
calculate a correlation coefficient using the electrical power grid phasors and the inverter phasors.

3. The solar power inverter of claim 2 wherein the controller is further configured to determine whether the solar power inverter is islanded with respect to the electrical power grid based upon the correlation coefficient.

4. The solar power inverter of claim 1 wherein the controller is further configured to:
identify multiple possible shifts of the inverter phasors relative to the electrical power grid phasors; and
for each possible shift, calculate a correlation coefficient using the electrical power grid phasors and the inverter phasors.

5. The solar power inverter of claim 4 wherein the controller is further configured to determine whether the solar power inverter is islanded with respect to the electrical power grid based upon the correlation coefficients calculated for each possible shift.

6. The solar power inverter of claim 1 wherein the controller is further configured to determine a state of the electrical power grid based upon the analysis of the electrical power grid phasors and the inverter phasors, wherein the state includes one of the following states: 1) the solar power inverter is islanded with respect to the electrical power grid; and 2) the electrical power grid is stable.

7. The solar power inverter of claim 6 wherein the controller is further configured to cause an action to be performed based upon the state of the electrical power grid, wherein the action includes at least one of the following: 1) shutting down the solar power inverter; 2) switching the solar power inverter to intentional island mode; and 3) providing support functionality for the electrical power grid.

8. The solar power inverter of claim 1 wherein the clock is further configured to synchronize the time according to a time associated with an electrical power grid phasor.

9. The solar power inverter of claim 1 wherein the first degree of accuracy is at least one order of magnitude more accurate than the second degree of accuracy.

10. A method, performed by an apparatus electrically coupled to an electrical power grid, of analyzing phasors, the method comprising:
receiving a first set of phasors, wherein the first set of phasors describe characteristics of power transmitted by the electrical power grid, and wherein the first set of phasors have associated timestamps having a first accuracy;
receiving a second set of phasors, wherein the second set of phasors describe characteristics of power at a point of common coupling of a power generation apparatus to the electrical power grid, and wherein the second set of phasors have associated timestamps having a second accuracy, wherein the second accuracy is less than the first accuracy; and
analyzing the first and second sets of phasors.

11. The method of claim 10, further comprising:
aligning the first set of phasors and the second set of phasors based upon associated timestamps; and
calculating a correlation coefficient using the first set of phasors and the second set of phasors.

12. The method of claim 10, further comprising:
identifying multiple possible shifts of the second set of phasors relative to the first set of phasors; and
for each possible shift, calculating a correlation coefficient using the first set of phasors and the second set of phasors.

13. The method of claim 10, further comprising:
receiving a time signal indicating a time having the second accuracy;
synchronizing a clock of the apparatus to the indicated time, such that the clock time has the second accuracy; and
utilizing the clock time to associate timestamps with the second set of phasors.

14. The method of claim 10, further comprising:
identifying a time from a timestamp associated with the first set of phasors;
synchronizing a clock of the apparatus to the identified time, such that the clock time has the second accuracy; and
utilizing the clock time to associate timestamps with the second set of phasors.

15. The method of claim 10 wherein the first accuracy is at least one order of magnitude more accurate than the second accuracy.

16. The method of claim 10 further comprising based upon the analysis, determining a state of the electrical power grid at the PCC.

17. A power generation apparatus electrically coupleable to an electric power grid transmitting alternating current (AC), the power generation apparatus comprising:
means for generating AC usable by the electrical power grid;
means for receiving first phasors generated at a location of the electrical power grid, wherein the first phasors are timestamped with times accurate to X microseconds;
means for maintaining time and synchronizing the time using a time signal, wherein the time is accurate to Y microseconds, where Y is at least 10×;
means for generating second phasors and timestamping the second phasors according to the time; and
means for analyzing the first and second phasors.

18. The power generation apparatus of claim 17 wherein means for analyzing the first and second phasors aligns the first phasors and the second phasors based upon associated timestamps and calculates a correlation coefficient using the first and second phasors.

19. The power generation apparatus of claim 17 wherein means for analyzing the first and second phasors identifies multiple possible shifts of the second phasors relative to the phasors and for each possible shift, calculates a correlation coefficient using the first and second phasors.
